(19) United States
(12) Patent Application Publication
(10) Pub. No.: US 2025/0365847 A1
(43) Pub. Date: Nov. 27, 2025

(54) CIRCUIT BOARD AND MANUFACTURING METHOD THEREOF

(71) Applicants: HongHengShen Electronical Technology(Huai’an)Co., Ltd., Jiangsu Province (CN); Avary Holding (Shenzhen) Co., Ltd., Shenzhen (CN); Garuda Technology Co., Ltd., New Taipei City (TW)

(72) Inventors: An XUE, Jiangsu Province (CN); Zhen GAO, Jiangsu Province (CN); Pan TANG, Jiangsu Province (CN)

(21) Appl. No.: 18/897,409

(22) Filed: Sep. 26, 2024

(30) Foreign Application Priority Data
May 24, 2024 (CN) 202410661755.X

(51) Int. Cl. H05K 1/02; H05K 1/11; H05K 1/18; H05K 3/10

(52) U.S. Cl. CPC H05K 1/0203; H05K 1/111; H05K 1/181; H05K 3/10; H05K 2201/066; H05K 2201/10416

(57) ABSTRACT

A circuit board includes a circuit base, an electronic component and a heat dissipation block. The circuit base has first and second surfaces, and a groove recessed from the second surface toward the first surface and has first and second side walls, and a bottom part adjacent to the first surface, where the width of the bottom part is smaller than the distance between the first and the second side walls. The circuit base includes first connection wiring and second connection wirings disposed on the first and the second side walls, first and second pads disposed on the bottom part and electrically connected to the first and the second connection wirings. The electronic component is disposed in the groove and is electrically connected to the first and the second connection wirings. The heat dissipation block is disposed in the groove and is thermally coupled to the electronic component.

### CROSS-REFERENCE TO RELATED APPLICATION

This application claims priority to Chinese Patent Application No. 202410661755.X, filed May 24, 2024, which is herein incorporated by reference in its entirety.

### BACKGROUND

### Field of Invention

The present disclosure relates to a circuit board and a method of manufacturing the same.

### Description of Related Art

Most of the current embedded chip circuit boards have the chip embedded in the circuit base, and the chip is electrically connected to the circuit base by microvia. However, in addition to considering whether the thickness and type of surface treatment on the chip is compatible with the drilling and plating process, the aforementioned method also has cost issues such as bare chip handling equipment, bare chip yield testing, and expensive sintering materials and low thermal expansion coefficient of circuit base.

Furthermore, with the development of communication technology, the size of embedded chip circuit boards installed in communication apparatus (such as mobile phones) is getting smaller and smaller, and the power consumption of the chips is also increasing, so saving the layout space of the circuit boards and improving the heat dissipation performance of the embedded chip circuit boards are one of the goals to be achieved in this technology field.

### SUMMARY

At least one embodiment of the present disclosure provides a circuit board that can improve heat dissipation and save the layout space of the circuit board, thereby improving reliability and reducing manufacturing costs.

At least another embodiment of the present disclosure provides a method of manufacturing the abovementioned circuit board. The method helps the above-mentioned circuit board improve heat dissipation and save the layout space of the circuit board, thereby improving reliability and reducing manufacturing costs.

The circuit board according to at least one embodiment of the present disclosure includes a circuit base, an electronic component, and a heat dissipation block. The circuit base has a first surface, a second surface opposite to the first surface, and a groove recessed in a direction from the second surface toward the first surface. The groove has a first side wall, a second side wall opposite to the first side wall, and a bottom part closer to the first surface than the first side wall and the second side wall, where the width of the bottom part is smaller than the distance between the first side wall and the second side wall. The circuit base includes a first connection wiring disposed on the first side wall, a second connection wiring disposed on the second side wall, a first pad disposed on the bottom part and electrically connected to the first connection wiring, and a second pad disposed on the bottom part and electrically connected to the second connection wiring. The electronic component is disposed in the groove and is electrically connected to the first connection wiring and the second connection wiring. The heat dissipation block is disposed in the groove, is located between the electronic component and the second surface, and is thermally coupled to the electronic component.

The method of manufacturing the circuit board according to at least another embodiment of the present disclosure includes the following steps. A copper clad laminate is provided. The copper clad laminate has a first initial surface and a second initial surface opposite to the first initial surface, and includes a first metal layer and a second metal layer, where the first metal layer has the first initial surface, and the second metal layer has the second initial surface. A portion of the copper clad laminate is removed to form a groove. The groove is recessed in a direction from the second initial surface toward the first initial surface, and has a bottom part, a first side wall, and a second side wall opposite to the first side wall. A connection metal layer is formed on the first side wall, on the second side wall, and on the bottom part. After the connection metal layer is formed, an electronic component is disposed in the groove and is mounted on the connection metal layer to electrically connect to the connection metal layer. After the electronic component is mounted on the connection metal layer, an initial resin is formed in the groove. A portion of the initial resin is removed to form a resin and to expose the electronic component. After the portion of the initial resin is removed to form the resin and to expose the electronic component, a heat dissipation metal layer is formed to thermally couple to the electronic component. The first metal layer, the second metal layer, the connection metal layer, and the heat dissipation metal layer are patterned.

The circuit board according to at least another embodiment of the present disclosure includes a circuit base, an electronic component, and a heat dissipation block. The circuit base has a first surface, a second surface opposite to the first surface, and a channel extending from the first surface to the second surface. The channel has a first side wall, a second side wall opposite to the first side wall, a first opening part closer to the first surface than the first side wall and the second side wall, a second opening part closer to the second surface than the first side wall and the second side wall, a first abutting surface located between the first opening part and the first side wall, and a second abutting surface located between the first opening part and the second side wall, where the first abutting surface and the second abutting surface are perpendicular to the first side wall and the second side wall, respectively, and the width of the first opening part and the width of the second opening part are both larger than the distance between the first side wall and the second side wall. The circuit base includes a first connection wiring disposed on the first abutting surface, and a second connection wiring disposed on the second abutting surface. The electronic component is disposed in the channel and is electrically connected to the first connection wiring and the second connection wiring. The heat dissipation block is disposed in the channel, is located between the electronic component and the second surface, and is thermally coupled to the electronic component.

It is to be understood that both the foregoing general descriptions and the following detailed descriptions are by examples, and are intended to provide further explanation of the present disclosure as claimed.

### BRIEF DESCRIPTION OF THE DRAWINGS

The present disclosure can be more fully understood by reading the following detailed description of the embodiments, with reference made to the accompanying drawings as follows:

FIG. 1 is a partial schematic cross-sectional view of a circuit board according to at least one embodiment of the present disclosure.

FIG. 2 is a schematic cross-sectional view of an electronic component according to at least one embodiment of the present disclosure.

FIGS. 3A to 3F are partial schematic cross-sectional views of the circuit board as shown in FIG. 1, at different manufacturing stages.

FIG. 4 is a partial schematic cross-sectional view of a circuit board according to at least another embodiment of the present disclosure.

FIG. 5A is a schematic cross-sectional view of an electronic component according to at least another embodiment of the present disclosure.

FIG. 5B is a schematic top view of an electronic component according to at least another embodiment of the present disclosure.

FIG. 6A is a schematic top view of a heat dissipation block according to at least another embodiment of the present disclosure.

FIG. 6B is a schematic cross-sectional view taken along line A-A′ of FIG. 6A.

FIGS. 7A to 7F are partial schematic cross-sectional views of the circuit board as shown in FIG. 4, at different manufacturing stages.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

In the following description, in order to clearly present the technical features of the present disclosure, the dimensions (such as length, width, thickness, and depth) of elements (such as layers, films, bases, and areas) in the drawings will be enlarged in unequal proportions. Therefore, the description and explanation of the following embodiments are not limited to the sizes and shapes presented by the elements in the drawings, but should cover the sizes, shapes, and deviations of the two due to actual manufacturing processes and/or tolerances. For example, the flat surface as shown in the drawings may have rough and/or non-linear characteristics, and the acute angle as shown in the drawings may be round. Therefore, the elements presented in the drawings in this case are mainly for illustrative purposes, and are not intended to accurately depict the actual shape of the elements, nor are they intended to limit the scope of patent applications in this case.

Furthermore, the words “about”, “approximately” or “substantially” used in the present disclosure not only cover the clearly stated numerical values and numerical ranges, but also cover those that can be understood by a person with ordinary knowledge in the technical field to which the present disclosure belongs. The permissible deviation range can be determined by the error generated during measurement, and the error is caused, for example, by limitations of the measurement system or process conditions. For example, two objects (such as the plane or traces of a base) are “substantially parallel” or “substantially perpendicular”, where “substantially parallel” and “substantially perpendicular” mean that parallelism and perpendicularity, respectively, between the two objects can include non-parallelism and non-perpendicularity caused by permissible deviation ranges.

The spatial relative terms used in the present disclosure, such as “below”, “under”, “above”, “on”, and the like, are intended to facilitate the recitation of a relative relationship between one element or feature and another as depicted in the figures. The true meaning of these spatial relative terms includes other orientations. For example, the relationship between one element and another may change from “below” and “under” to “above” and “on” when the figure is turned 180 degrees up or down. In addition, spatially relative descriptions used in the present disclosure should be interpreted in the same manner.

It should be understood that while the present disclosure may use terms such as “first”, “second”, “third”, etc. to describe various elements or features, these elements or features should not be limited by these terms. These terms are primarily used to distinguish one element from another, or one feature from another. In addition, the term “or” as used in the present disclosure may include, as appropriate, any one or a combination of the listed items in association.

Although a series of operations or steps are used to illustrate the manufacturing method in the present disclosure, the order shown in these operations or steps should not be construed as a limitation of the present disclosure. For example, some operations or steps may be performed in a different order and/or concurrently with other steps. In addition, each operation or step described herein may include several sub-steps or actions.

Moreover, the present disclosure may be implemented or applied in various other specific embodiments, and the details of the present disclosure may be combined, modified, and altered in various embodiments based on different viewpoints and applications, without departing from the idea of the present disclosure.

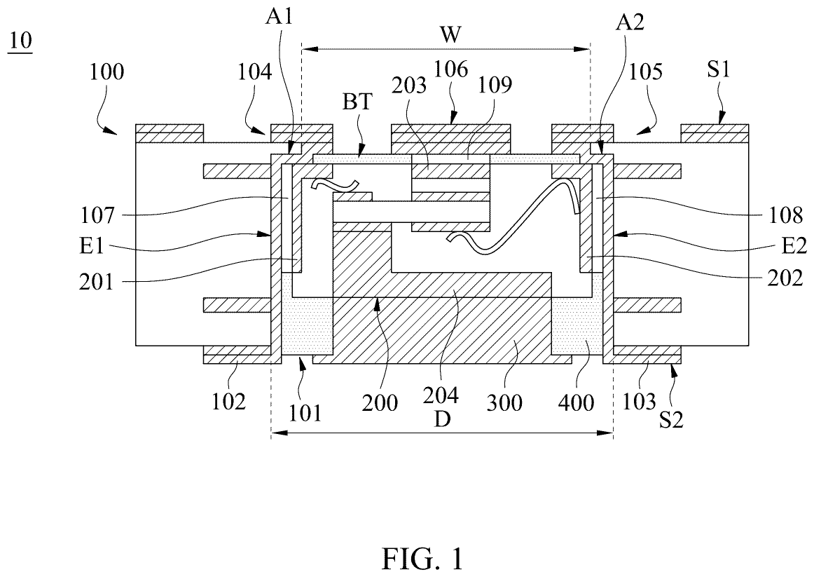

FIG. 1 is a partial schematic cross-sectional view of a circuit board 10 according to at least one embodiment of the present disclosure. Referring to FIG. 1, the circuit board 10 includes a circuit base 100, an electronic component 200 and a heat dissipation block 300. The circuit base 100 has a first surface S1, a second surface S2 opposite to the first surface S1, and a groove 101 recessed from the second surface S2 toward the first surface S1. The groove 101 has a first side wall E1, a second side wall E2 opposite to the first side wall E1, and a bottom part BT closer to the first surface S1 than the first side wall E1 and the second side wall E2. The width W of the bottom part BT is smaller than the distance D between the first side wall E1 and the second side wall E2.

The circuit base 100 includes a first connection wiring 102, a second connection wiring 103, a first pad 104 and a second pad 105. The first connection wiring 102 is disposed on the first side wall E1, and the second connection wiring 103 is disposed on the second side wall E2. The first pad 104 is disposed on the bottom part BT and is electrically connected to the first connection wiring 102, and the second pad 105 is disposed on the bottom part BT and is electrically connected to the second connection wiring 103. The electronic component 200 is disposed in the groove 101 and is electrically connected to the first connection wiring 102 and the second connection wiring 103. The heat dissipation block 300 is disposed in the groove 101, is located between the electronic component 200 and the second surface S2, and is thermally coupled to the electronic component 200.

The electronic component 200 is electrically connected to the circuit base 100 through the first connection wiring 102 disposed on the first side wall E1 of the groove 101 and the second connection wiring 103 disposed on the second side wall E2 of the groove 101, thereby reducing the use of conductive through holes or conductive blind holes for connection. The electronic component 200 and the heat dissipation block 300 are both disposed in the groove 101 of the circuit base 100, so the layout space of the circuit board can be saved and the heat dissipation performance can be improved. In addition, general soldering materials and general plates can be used, and there is no need to use expensive silver sintering materials or low thermal expansion coefficient plates, thereby reducing costs.

In addition, by the stepped design formed by the width W of the bottom part BT being smaller than the distance D between the first side wall E1 and the second side wall E2, the range of the soldering layer between the electronic component 200 and the first connection wiring 102 and the second connection wiring 103 can be limited, and a stable electrical connection can be formed between the electronic component 200 and the first connection wiring 102 and the second connection wiring 103 to enhance the reliability.

Referring to FIG. 1, the circuit board 10 further includes a resin 400 disposed in the groove 101, located at the bottom part BT, and surrounding the heat dissipation block 300. In some embodiments, the thermal conductivity of the resin 400 ranges from 3 to 12 W/mk, and can help the electronic component 200 dissipate heat through the aforementioned placement. The material of the heat dissipation block 300 may include copper. The heat dissipation block 300 may be directly in contact with the electronic component 200 to thermally couple to the electronic component 200, or thermally couple to the electronic component 200 through a thermal conductive structure disposed between the heat dissipation block 300 and the electronic component 200.

In addition, as shown in FIG. 1, the groove 101 has a first abutting surface A1 between the bottom part BT and the first side wall E1 and a second abutting surface A2 between the bottom part BT and the second side wall E2, where the first abutting surface A1 and the second abutting surface A2 are substantially perpendicular to the first side wall E1 and the second side wall E2, respectively. The first connection wiring 102 extends to the first abutting surface A1 and the bottom part BT and is in contact with the first pad 104, and the second connection wiring 103 extends to the second abutting surface A2 and the bottom part BT and is in contact with the second pad 105.

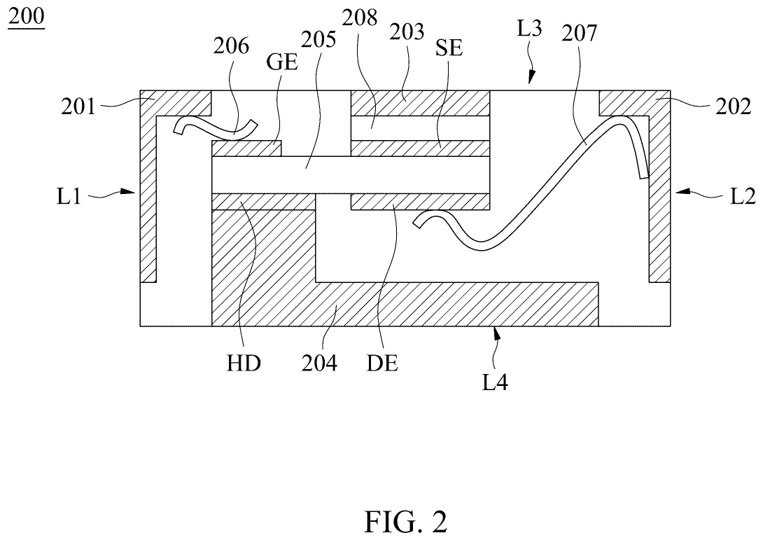

FIG. 2 is a schematic cross-sectional view of an electronic component 200 according to at least one embodiment of the present disclosure. Referring to FIG. 2, the electronic component 200 has a first side L1, a second side L2 opposite to the first side L1, a third side L3 between the first side L1 and the second side L2, and a fourth side L4 opposite to the third side L3. The electronic component 200 includes a first external electrode 201 disposed on the first side L1, a second external electrode 202 disposed on the second side L2, a third external electrode 203 disposed on the third side L3, and a heat dissipation part 204 disposed on the fourth side L4.

As shown in FIG. 2, the electronic component 200 further includes a chip 205, a first electrode GE, a second electrode DE, a third electrode SE, a heat dissipation layer HD, conductive wires 206, 207 and a fourth soldering layer 208. The first electrode GE, the second electrode DE, the third electrode SE and the heat dissipation layer HD are disposed on the chip 205. The first electrode GE is electrically connected to the first external electrode 201 through the conductive wire 206, and the second electrode DE is electrically connected to the first external electrode 201 through the conductive wire 207. The third electrode SE is electrically connected to the third external electrode 203 through the fourth soldering layer 208, and the heat dissipation layer HD is thermally coupled to the heat dissipation part 204. The heat dissipation layer HD may be directly in contact with the heat dissipation part 204 to thermally couple to the heat dissipation part 204, or thermally couple to the heat dissipation part 204 through a thermal conductive structure disposed between the heat dissipation layer HD and the heat dissipation part 204.

In some embodiments, the chip 205 may be a power semiconductor device. For example, the chip 205 may be a silicon carbide power device, and the first electrode GE, the second electrode DE, and the third electrode SE may be the gate, the drain and the source of the chip 205, respectively. In addition, the material of the heat dissipation part 204 may include copper and have a thickness not less than 18 micrometers, which can effectively dissipate heat and prevent the chip 205 from being damaged during the hole opening process.

Referring to FIG. 1 and FIG. 2, the first external electrode 201 disposed on the first side L1 extends to the third side L3 and is in contact with the first connection wiring 102 located on the first abutting surface A1. The second external electrode 202 disposed on the second side L2 extends to the third side L3 and is in contact with the second connection wiring 103 located on the second abutting surface A2. Through the aforementioned design, the electrical connection area between the first external electrode 201 and the first connection wiring 102, and the electrical connection area between the second external electrode 202 and the second connection wiring 103 can be increased, thereby improving reliability.

As shown in FIG. 1 and FIG. 2, the circuit based 100 further includes a third pad 106 disposed on the bottom part BT and electrically connected to the third external electrode 203. The heat dissipation part 204 is thermally coupled to the heat dissipation block 300. The heat dissipation part 204 may be directly in contact with the heat dissipation block 300 to thermally couple to the heat dissipation block 300, or thermally couple to the heat dissipation block 300 through a thermal conductive structure disposed between the heat dissipation part 204 and the heat dissipation block 300.

In addition, the circuit board 10 further includes a first soldering layer 107, a second soldering layer 108, and a third soldering layer 109. In some embodiments, the materials of the first soldering layer 107, the second soldering layer 108, and the third soldering layer 109 may include tin.

The first soldering layer 107 is disposed between the first external electrode 201 and the first connection wiring 102 to electrically connect the first external electrode 201 and the first connection wiring 102. The second soldering layer 108 is disposed between the second external electrode 202 and the second connection wiring 103 to electrically connected to the second external electrode 202 and the second connection wiring 103. The third soldering layer 109 is disposed between the third external electrode 203 and the third pad 106 to electrically connect the third external electrode 203 and the third pad 106.

In detail, the first soldering layer 107 is disposed between the first external electrode 201 and the first connection wiring 102, and is located on the first side wall E1. The second soldering layer 108 is disposed between the second external electrode 202 and the second connection wiring 103, and is located on the second side wall E2. The third soldering layer 109 is disposed between the third external electrode 203 and the third pad 106, and is located on the bottom part BT. In some embodiments, the first pad 104, the second pad 105, and the third pad 106 may be electrically connected to an external circuit.

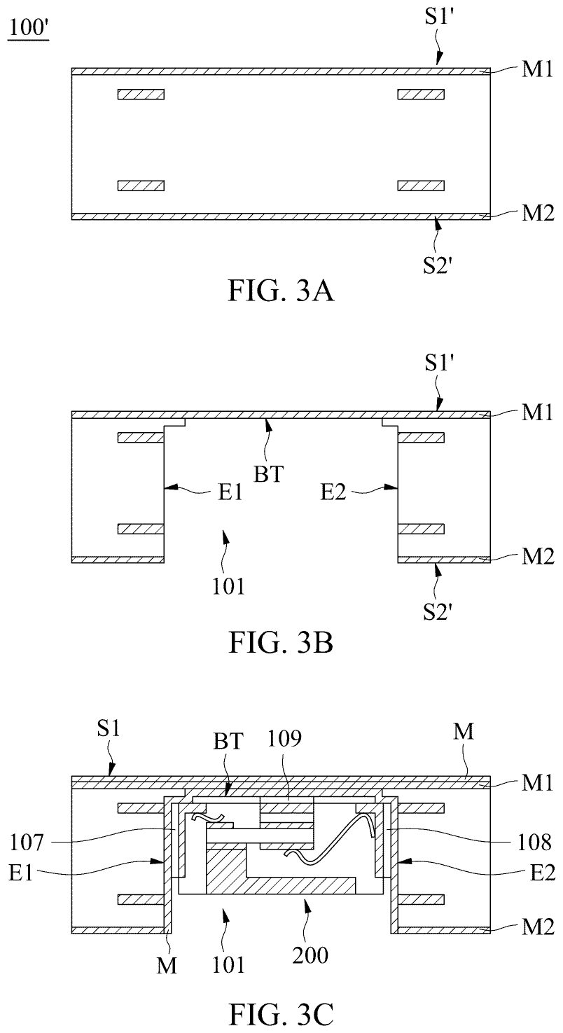

FIGS. 3A to 3F are partial schematic cross-sectional views of the circuit board 10 as shown in FIG. 1, at different manufacturing stages. First, referring to FIG. 3A, a copper clad laminate 100′ is provided. The copper clad laminate 100′ has a first initial surface S1′ and a second initial surface S2′ opposite to the first initial surface S1′, and includes a first metal layer M1 and a second metal layer M2. The first metal layer M1 has the first initial surface S1′, and the second metal layer M2 has the second initial surface S2′. In some embodiments, the materials of the first metal layer M1 and the second metal layer M2 may include copper.

Referring to FIG. 3B, a portion of the copper clad laminate 100′ is removed to form a groove 101. The groove 101 is recessed from the second initial surface S2′ toward the first initial surface S1′. The groove 101 has a bottom part BT, a first side wall E1 and a second side wall E2 opposite the first side wall E1.

In detail, a first portion of the copper clad laminate 100′ is removed to form the first side wall E1 and the second side wall E2. Next, after the first sidewall E1 and the second sidewall E2 are formed, a second portion of the copper clad laminate 100′ is removed to form the bottom part BT. Since the width W of the bottom part BT is smaller than the distance D between the first side wall E1 and the second side wall E2, and the depth of the bottom part BT is also smaller than the height of the first side wall E1 and the second side wall E2, the step of removing the first portion of the copper clad laminate 100′ to form the first side wall E1 and the second side wall E2 may be implemented by a machining process such as a milling machining process, and the step of removing the second portion of the copper clad laminate 100′ to form the bottom part BT may be implemented by a laser process which is more precise than a machining process.

Referring to FIG. 3C, a connection metal layer M is formed on the first side wall E1, on the second side wall E2 and on the bottom part BT. After the connection metal layer M is formed, an electronic component 200 is disposed in the groove 101, and is mounted on the connection metal layer M to electrically connect to the connection metal layer M. In some embodiments, the connection metal layer M may be further formed on the first metal layer M1, and the connection metal layer M formed on the first metal layer M1 has a first surface S1.

The material of the connection metal layer M may include copper, and the connection metal layer M may be formed by an electroplating process. In addition, the electronic component 200 may be mounted on the connection metal layer M by a soldering process, that is, a first soldering layer 107, a second soldering layer 108 and a third soldering layer 109 are formed, as shown in FIG. 3C.

Referring to FIG. 3D, after the electronic component 200 is mounted on the connection metal layer M, an initial resin 400′ is formed in the groove 101. Next, referring to FIG. 3E, a portion of the initial resin 400′ is removed to form a resin 400 and to expose the electronic component 200. In some embodiments, removing the portion of the initial resin 400′ to form the resin 400 and to expose the electronic components 200 may be implemented by a laser process.

Referring to FIG. 3F, after the portion of the initial resin 400′ is removed to form the resin 400 and to expose the electronic component 200, a heat dissipation metal layer HM is formed to thermally couple to the electronic component 200. Next, the first metal layer M1, the second metal layer M2, the connection metal layer M and the heat dissipation metal layer HM are patterned. In some embodiments, the heat dissipation metal layer HM may be further formed on the second metal layer M2, and the heat dissipation metal layer HM formed on the second metal layer M2 has a second surface S2. Patterning the first metal layer M1, the second metal layer M2, the connection metal layer M and the heat dissipation metal layer HM may be implemented by an etching process. The heat dissipation metal layer HM may be directly in contact with the electronic component 200 to thermally couple to the electronic component 200, or thermally couple to the electronic component 200 through a thermal conductive structure formed between the heat dissipation metal layer HM and the electronic component 200.

In detail, the step of patterning the first metal layer M1, the second metal layer M2, the connection metal layer M and the heat dissipation metal layer HM may include forming the first connection wiring 102, the second connection wiring 103, the first pad 104, the second pad 105, the third pad 106 and the heat dissipation block 300 of the circuit base 100 as shown in FIG. 1.

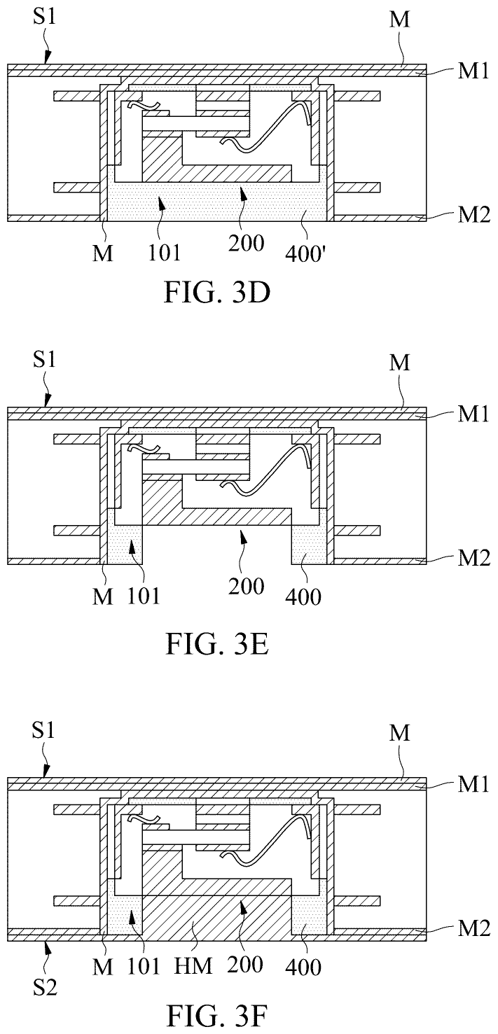

FIG. 4 is a partial schematic cross-sectional view of a circuit board 10A according to at least another embodiment of the present disclosure. Referring to FIG. 4, the circuit board 10A includes a circuit base 100A, an electronic component 200A, a heat dissipation block 300A and a fastening member 500. The circuit base 100A has a first surface S1, a second surface S2 opposite to the first surface S1, and a channel 101A extending from the first surface S1 to the second surface S2.

The channel 101A has a first side wall E1, a second side wall E2 opposite to the first side wall E1, a first opening part O1 closer to the first surface S1 than the first side wall E1 and the second side wall E2, a second opening part O2 closer to the second surface S2 than the first side wall E1 and the second side wall E2, a first abutting surface A1 between the first opening part O1 and the first side wall E1, and a second abutting surface A2 between the first opening part O1 and the second side wall E2. The first abutting surface A1 and the second abutting surface A2 are substantially perpendicular to the first side wall E1 and the second side wall E2, respectively. The width W1 of the first opening part O1 and the width W2 of the second opening part O2 are both larger than the distance D between the first side wall E1 and the second side wall E2.

The circuit base 100A includes a first connection wiring 102A and a second connection wiring 103A. The first connection wiring 102A is disposed on the first abutting surface A1, and the second connection wiring 103A is disposed on the second abutting surface A2. The electronic component 200A is disposed in the channel 101A and is electrically connected to the first connection wiring 102A and the second connection wiring 103A.

The heat dissipation block 300A is disposed in the channel 101A, is located between the electronic component 200A and the second surface S2, and is thermally coupled to the electronic component 200A. The fastening member 500 fixes the electronic component 200A and the heat dissipation block 300A. The heat dissipation block 300A may be directly in contact with the electronic component 200A to thermally couple to the electronic component 200A, or thermally couple to the electronic component 200A through a thermal conductive structure disposed between the heat dissipation block 300A and the electronic component 200A.

The electronic component 200A and the heat dissipation block 300A are fixed in the channel 101A by the fastening member 500, and the channel 101A has a stepped design with the width W1 of the first opening part O1 and the width W2 of the second opening part O2 being larger than the distance D between the first side wall E1 and the second side wall E2, respectively, to achieve a stable and detachable circuit board, and the electronic component 200A is electrically connected to the circuit base 100A by the first connection wiring 102A and the second connection wiring 103A disposed on the first abutting surface A1 and the second abutting surface A2, respectively. In addition, the electronic component 200A and the heat dissipation block 300A are both disposed in the channel 101A of the circuit base 100A, so the layout space of the circuit board can be saved and the heat dissipation performance can be improved.

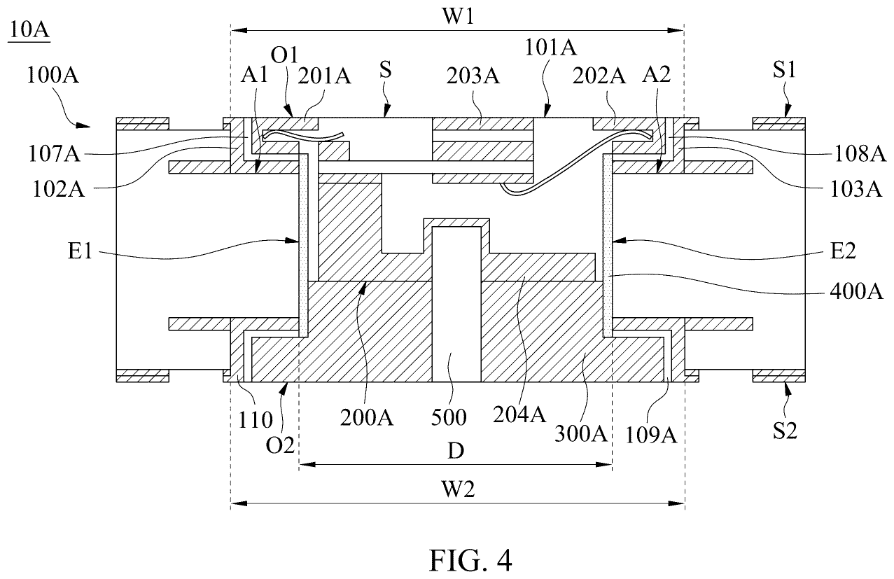

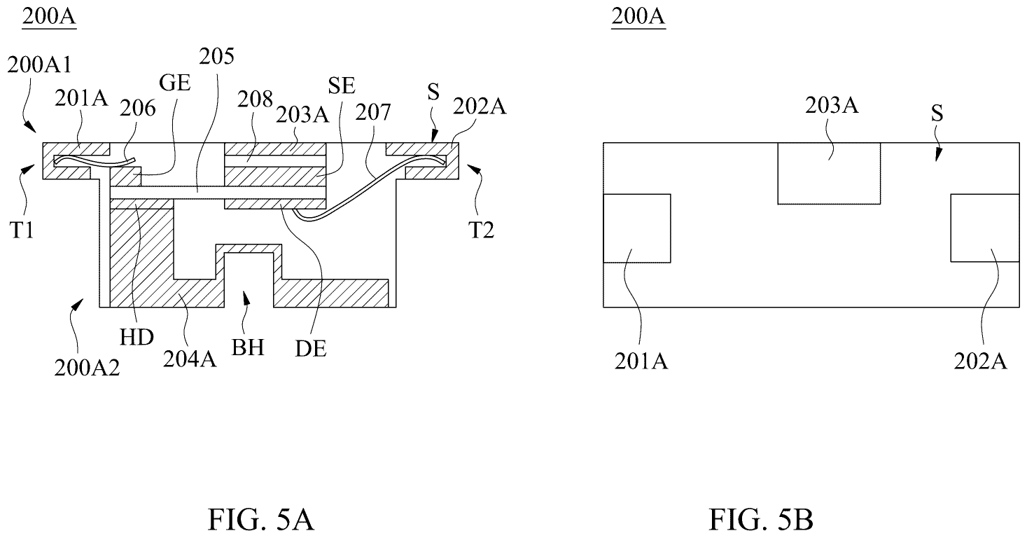

FIG. 5A is a schematic cross-sectional view of an electronic component 200A according to at least another embodiment of the present disclosure. FIG. 5B is a schematic top view of an electronic component 200A according to at least another embodiment of the present disclosure. Referring to FIG. 4, FIG. 5A and FIG. 5B, the electronic component 200A has a chassis 200A1 and an extension part 200A2 extending from the chassis 200A1 in the normal line of the chassis 200A1. The electronic component 200A includes a first external electrode 201A, a second external electrode 202A, a third external electrode 203A, and a heat dissipation part 204A.

The heat dissipation part 204A is disposed on a side of the extension part 200A2 away from the chassis 200A1 and is thermally coupled to the heat dissipation block 300A. The heat dissipation part 204A may be directly in contact with the heat dissipation block 300A to thermally couple to the heat dissipation block 300A, or thermally couple to the heat dissipation block 300A through a thermal conductive structure disposed between the heat dissipation part 204A and the heat dissipation block 300A. In addition, the materials of the heat dissipation block 300A and the heat dissipation part 204A may include copper.

The chassis 200A1 has a first end T1 and a second end T2 opposite to each other and protruding from the extension part 200A2, and a surface S located between the first end T1 and the second end T2. That is, the width of the chassis 200A1 is larger than the width of the extension part 200A2. The first external electrode 201A is disposed on the first end T1 and extends to the surface S, the second external electrode 202A is disposed on the second end T2 and extends to the surface S, and the third external electrode 203A is disposed on the surface S.

As shown in FIG. 5B, since the first external electrode 201A, the second external electrode 202A and the third external electrode 203A are all disposed on the surface S of the electronic component 200A, electrical testing may be facilitated. In some embodiments, the surface S of the electronic component 200A may be coplanar with the first surface S1 of the circuit base 100A, and the first external electrode 201A, the second external electrode 202A, and the third external electrode 203A may be used directly as the pads for electrically connecting to the external circuit.

As shown in FIG. 5A, the electronic component 200A further includes a chip 205, a first electrode GE, a second electrode DE, a third electrode SE, a heat dissipation layer HD, conductive wires 206, 207 and a fourth soldering layer 208. The aforementioned elements of the electronic component 200A of FIG. 5A and the elements with the same labels of the electronic component 200 of FIG. 2 have the same structures, materials, and relative position relationships, so the same features will not be repeated.

Referring to FIG. 4 and FIG. 5A, the circuit board 10A further includes a first soldering layer 107A, a second solder layering 108A, and a buffer member 400A. The first soldering layer 107A is disposed between the first external electrode 201A and the first connection wiring 102A to electrically connect to the first external electrode 201A and the first connection wiring 102A. The second soldering layer 108A is disposed between the second external electrode 202A and the second connection wiring 103A to electrically connect to the second external electrode 202A and the second connection wiring 103A. The buffer member 400A is disposed on the first side wall E1 and the second side wall E2 and surrounds the extension part 200A2.

In detail, the first connection wiring 102A and the second connection wiring 103A are not only disposed on the first abutting surface A1 and the second abutting surface A2, respectively, but also extend to the sidewall of the first opening part O1. The chassis 200A1 of the electronic component 200A is disposed in the first opening part O1. The first soldering layer 107A and the second soldering layer 108A are L-shaped, respectively. The first soldering layer 107A is disposed between the first external electrode 201A located at the first end T1 of the chassis 200A1 and the first connection wiring 102A. The second soldering layer 108A is disposed between the second external electrode 202A located at the second end T2 of the chassis 200A1 and the second connection wiring 103A.

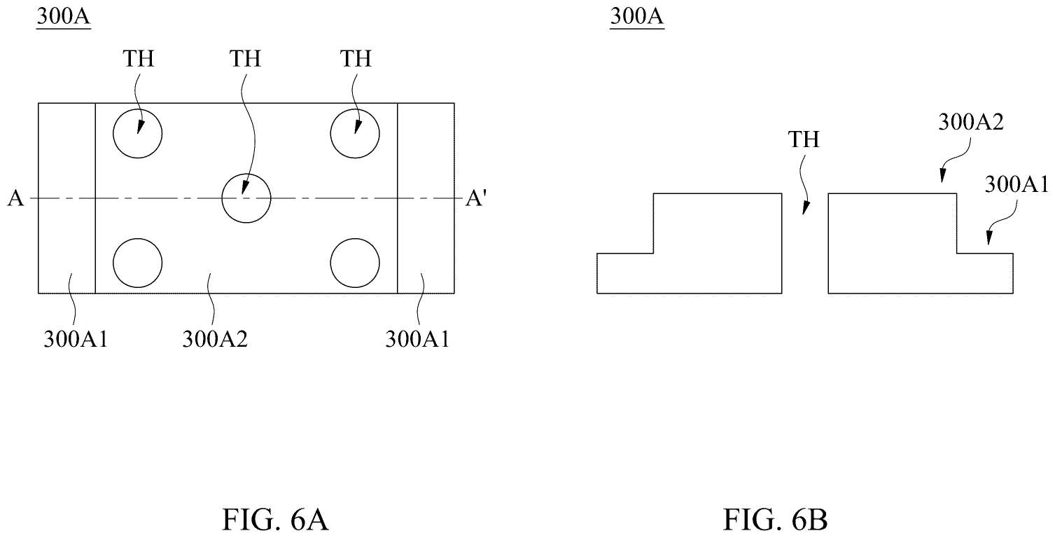

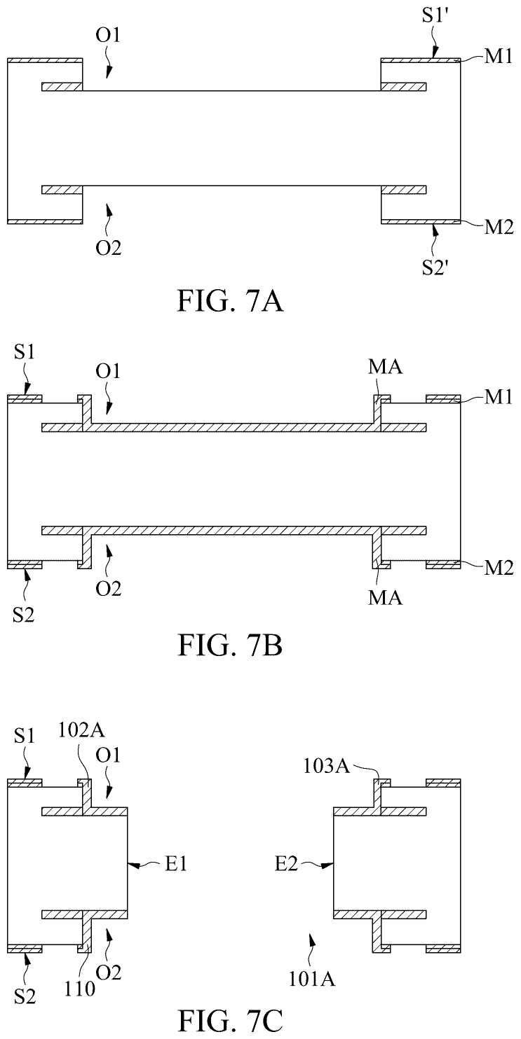

FIG. 6A is a schematic top view of a heat dissipation block 300A according to at least another embodiment of the present disclosure. FIG. 6B is a schematic cross-sectional view taken along line A-A′ of FIG. 6A. Referring to FIG. 4, FIG. 6A and FIG. 6B, the heat dissipation block 300A has a base 300A1 and a protruding part 300A2 with the width smaller than the width of the base 300A1 and extending from the base 300A1 in the normal line of the base 300A1. The circuit base 100A further includes a thermal conductive layer 110 disposed on the sidewall of the second opening part O2.

The circuit board 10A further includes a third soldering layer 109A. The third soldering layer 109A is disposed between the protruding part 300A2 and the thermal conductive layer 110 to thermally couple to the protruding part 300A2 and the thermal conductive layer 110. In addition, the buffer member 400A not only surrounds the extension part 200A2 of the electronic component 200A, but also surrounds the protruding part 300A2 of the heat dissipation block 300A. In some embodiments, the materials of the first soldering layer 107A, the second soldering layer 108A, and the third soldering layer 109A may include tin.

As shown in FIGS. 6A and 6B, the heat dissipation block 300A has one or more through holes TH penetrating the heat dissipation block 300A. As shown in FIG. 5A, the extension part 200A2 of the electronic component 200A has a blind hole BH corresponding to the through hole TH of the heat dissipation block 300A. As shown in FIG. 4, the fastening member 500 is disposed in the through hole TH and the blind hole BH to fix the electronic component 200A and the heat dissipation block 300A. In some embodiments, the fastening member 500 may be a screw, the through hole TH has a screw threaded structure (not shown), and the fastening member 500 and the through hole TH are detachably connected through the internal screw threaded structure and the external screw threaded structure.

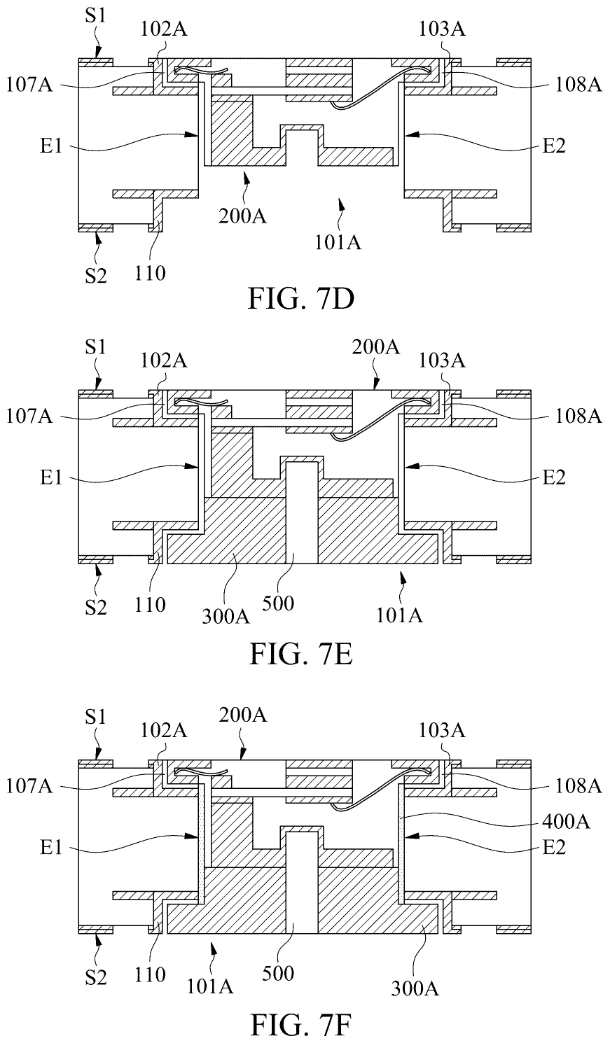

FIGS. 7A to 7F are partial schematic cross-sectional views of the circuit board as shown in FIG. 4, at different manufacturing stages. First, the steps of providing the copper clad laminate 100′ are the same as those in FIG. 3A, and the element structures, materials, processes and relative position relationships in the steps are the same, so the same features will not be repeated.

Next, referring to FIG. 7A to FIG. 7C, a portion of the copper clad laminate 100′ is removed to form a channel 101A, and the channel 101A extends from the first initial surface S1′ to the second initial surface S2′, and has a first side wall E1 and a second side wall E2 opposite to each other, a first opening part O1 closer to the first initial surface S1′ than the first side wall E1 and the second side wall E2, and a second opening O2 closer to the second initial surface S2′ than the first side wall E1 and the second side wall E2. A first connection wiring 102A and the second connection wiring 103A are formed on the sidewall of the first opening part O1. A thermal conductive layer 110 is formed on the sidewall of the second opening part O2.

In detail, as shown in FIG. 7A, a first portion of the copper clad laminate 100′ is removed to form the first opening part O1 and the second opening part O2. As shown in FIG. 7B, after the first opening part O1 and the second opening part O2 are formed, a metal layer MA is formed in the first opening part O1 and the second opening part O2. Next, the first metal layer M1, the second metal layer M2, and the metal layer MA are patterned. In some embodiments, the metal layer MA may be formed on the first metal layer M1 and the second metal layer M2, respectively, and the metal layer MA formed on the first metal layer M1 has a first surface S1, and the metal layer MA formed on the second metal layer M2 has a second surface S2.

The step of removing the first portion of the copper clad laminate 100′ to form the first opening part O1 and the second opening part O2 can be implemented by a machining process, such as milling machining process. The material of the metal layer MA may include copper, and the metal layer MA may be formed by an electroplating process. Patterning the first metal layer M1, the second metal layer M2 and the metal layer MA can be implemented by an etching process.

As shown in FIG. 7C, after the first metal layer M1, the second metal layer M2 and the metal layer MA are patterned, a second portion of the copper clad laminate 100′ is removed to form the first sidewall E1 and the second sidewall E2, and a portion of the metal layer MA is removed to form the first connection wiring 102A and the second connection wiring 103A on the sidewall of the first opening part O1 and the thermal conductive layer 110 on the sidewall of the second opening part O2. The width W1 of the first opening part O1 and the width W2 of the second opening part O2 are both larger than the distance D between the first side wall E1 and the second side wall E2, as shown in FIG. 4.

Referring to FIG. 7D, after the first connection wiring 102A, the second connection wiring 103A and the thermal conductive layer 110 are formed, an electronic component 200A is disposed in the channel 101A and is mounted on the first connection wiring 102A and the second connection wiring 103A to electrically connect to the first connection wiring 102A and the second connection wiring 103A. The electronic component 200A may be mounted on the first connection wiring 102A and the second connection wiring 103A by a soldering process, that is, a first soldering layer 107A and a second soldering layer 108A are formed, as shown in FIG. 7D.

Referring to FIG. 7E, after the electronic component 200A is mounted on the first connection wiring 102A and the second connection wiring 103A, a heat dissipation block 300A is disposed in the channel 101A, and the electronic component 200A and the heat dissipation block 300A are fixed by a fastener member 500.

Referring to FIG. 7F, after the electronic component 200A and the heat dissipation block 300A are fixed by the fastener member 500, a buffer member 400A is formed on the first side wall E1 and the second side wall E2 and surrounds the electronic component 200A and the heat dissipation block 300A. Next, a third soldering layer 109A is formed between the thermal conductive layer 110 and the heat dissipation block 300A to thermally couple to the thermal conductive layer 110 and the heat dissipation block 300A, as shown in FIG. 4.

In summary, in the abovementioned circuit board and its manufacturing method in at least one embodiment of the present disclosure, the electronic component is electrically connected to the circuit base through the connection wiring disposed in the groove or the channel of the circuit base, thereby reducing the use of conductive through holes or conductive blind holes for connection. The electronic component and the heat dissipation block are both disposed in the groove or the channel of the circuit base, so the layout space of the circuit board can be saved and the heat dissipation performance can be improved. General soldering materials and general plates can be used, and there is no need to use expensive silver sintering materials or low thermal expansion coefficient plates, thereby reducing costs. Through the stepped design of the groove and the channel, a stable electrical connection can be formed between the electronic component and the circuit base to enhance the reliability. In addition, the detachable circuit board is achieved by fixing the electronic component and the heat dissipation block in the channel of the circuit base with the fastener member.

Although the present disclosure has been described in considerable details with reference to certain embodiments thereof, other embodiments are possible. Therefore, the spirit and scope of the appended claims should not be limited to the descriptions of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A circuit board, comprising:
a circuit base, having a first surface, a second surface opposite to the first surface, and a groove recessed in a direction from the second surface toward the first surface, wherein the groove has a first side wall, a second side wall opposite to the first side wall, and a bottom part closer to the first surface than the first side wall and the second side wall, wherein a width of the bottom part is smaller than a distance between the first side wall and the second side wall, wherein the circuit base comprises:
a first connection wiring, disposed on the first side wall;
a second connection wiring, disposed on the second side wall;
a first pad, disposed on the bottom part and electrically connected to the first connection wiring; and
a second pad, disposed on the bottom part and electrically connected to the second connection wiring;
an electronic component, disposed in the groove and electrically connected to the first connection wiring and the second connection wiring; and
a heat dissipation block, disposed in the groove, located between the electronic component and the second surface, and thermally coupled to the electronic component.

2. The circuit board of claim 1, further comprising:
a resin, disposed in the groove, located at the bottom part, and surrounding the heat dissipation block.

3. The circuit board of claim 1, wherein the groove has a first abutting surface and a second abutting surface, the first abutting surface is located between the bottom part and the first side wall, and the second abutting surface is located between the bottom part and the second side wall, wherein the first abutting surface and the second abutting surface are perpendicular to the first side wall and the second side wall, respectively, the first connection wiring extends to the first abutting surface and the bottom part to be in contact with the first pad, and the second connection wiring extends to the second abutting surface and the bottom part to be in contact with the second pad.

4. The circuit board of claim 1, wherein the electronic component has a first side, a second side opposite to the first side, a third side between the first side and the second side, and a fourth side opposite to the third side, wherein the electronic component comprises:
a first external electrode, disposed on the first side;
a second external electrode, disposed on the second side;
a third external electrode, disposed on the third side, wherein the circuit base further comprises a third pad disposed on the bottom part and electrically connected to the third external electrode; and
a heat dissipation part, disposed on the fourth side and thermally coupled to the heat dissipation block.

5. The circuit board of claim 4, wherein a thickness of the heat dissipation part is not less than 18 micrometers.

6. The circuit board of claim 4, further comprising:
a first soldering layer, disposed between the first external electrode and the first connection wiring to electrically connect to the first external electrode and the first connection wiring;
a second soldering layer, disposed between the second external electrode and the second connection wiring to electrically connect to the second external electrode and the second connection wiring; and
a third soldering layer, disposed between the third external electrode and the third pad to electrically connect to the third external electrode and the third pad.

7. A method of manufacturing a circuit board, comprising:
providing a copper clad laminate, wherein the copper clad laminate has a first initial surface and a second initial surface opposite to the first initial surface, and comprises a first metal layer and a second metal layer, wherein the first metal layer has the first initial surface, and the second metal layer has the second initial surface;
removing a portion of the copper clad laminate to form a groove, wherein the groove is recessed in a direction from the second initial surface toward the first initial surface, and has a bottom part, a first side wall, and a second side wall opposite to the first side wall;
forming a connection metal layer on the first side wall, on the second side wall, and on the bottom part;
after the connection metal layer is formed, disposing an electronic component in the groove and mounting the electronic component on the connection metal layer to electrically connect to the connection metal layer;
after the electronic component is mounted on the connection metal layer, forming an initial resin in the groove;
removing a portion of the initial resin to form a resin and to expose the electronic component;
after the portion of the initial resin is removed to form the resin and to expose the electronic component, forming a heat dissipation metal layer to thermally couple to the electronic component; and
patterning the first metal layer, the second metal layer, the connection metal layer, and the heat dissipation metal layer.

8. The method of manufacturing the circuit board of claim 7, wherein the step of removing the portion of the copper clad laminate to form the groove comprises:
removing a first portion of the copper clad laminate to form the first side wall and the second side wall; and
after the first side wall and the second side wall are formed, removing a second portion of the copper clad laminate to form the bottom part, wherein a width of the bottom part is smaller than a distance between the first side wall and the second side wall.

9. A circuit board, comprising:
a circuit base, having a first surface, a second surface opposite to the first surface, and a channel extending from the first surface to the second surface, wherein the channel has a first side wall, a second side wall opposite to the first side wall, a first opening part closer to the first surface than the first side wall and the second side wall, a second opening part closer to the second surface than the first side wall and the second side wall, a first abutting surface located between the first opening part and the first side wall, and a second abutting surface located between the first opening part and the second side wall, wherein the first abutting surface and the second abutting surface are perpendicular to the first side wall and the second side wall, respectively, a width of the first opening part and a width of the second opening part are both larger than a distance between the first side wall and the second side wall, wherein the circuit base comprises:
a first connection wiring, disposed on the first abutting surface; and
a second connection wiring, disposed on the second abutting surface;
an electronic component, disposed in the channel and electrically connected to the first connection wiring and the second connection wiring; and
a heat dissipation block, disposed in the channel, located between the electronic component and the second surface, and thermally coupled to the electronic component.

10. The circuit board of claim 9, wherein the electronic component has a chassis and an extension part extending from the chassis in a normal line of the chassis, wherein the chassis has a first end and a second end protruding from the extension part and opposite to each other, and a surface located between the first end and the second end.

11. The circuit board of claim 10, wherein the electronic component comprises:
a first external electrode, disposed on the first end and extending to the surface;
a second external electrode, disposed on the second side and extending to the surface;
a third external electrode, disposed on the third surface; and
a heat dissipation part, disposed on a side of the extension part away from the chassis and thermally coupled to the heat dissipation block.

12. The circuit board of claim 10, wherein the surface of the electronic component is coplanar with the first surface of the circuit base.

13. The circuit board of claim 10, further comprising a fastening member, wherein the heat dissipation block has a through hole, and the extension part has a blind hole corresponding to the through hole, wherein the fastening member is disposed in the through hole and the blind hole to fix the electronic component and the heat dissipation block.

14. The circuit board of claim 13, wherein the fastening member comprises a screw.

15. The circuit board of claim 11, further comprising:
a first soldering layer, disposed between the first external electrode and the first connection wiring to electrically connect to the first external electrode and the first connection wiring;
a second soldering layer, disposed between the second external electrode and the second connection wiring to electrically connect to the second external electrode and the second connection wiring; and
a buffer member, disposed on the first side wall and the second side wall and surrounding the extension part.

16. The circuit board of claim 15, wherein the heat dissipation block has a base and a protruding part with a width smaller than a width of the base and extending from the base in a normal line of the base, wherein the circuit base further comprises a thermal conductive layer disposed on a sidewall of the second opening part.

17. The circuit board of claim 16, wherein the circuit board further comprises:
a third soldering layer, disposed between the protruding part and the thermal conductive layer to thermally couple to the protruding part and the thermal conductive layer.

18. The circuit board of claim 16, wherein the buffer member further surrounds the protruding part.
